(19) United States
(12) Patent Application Publication
(10) Pub. No.: US 2015/0136449 A1
(43) Pub. Date: May 21, 2015

(54) MULTILAYERED WIRING SUBSTRATE

(71) Applicant: NGK Spark Plug Co., Ltd., Nagoya-shi (JP)

(72) Inventors: Daisuke YAMASHITA, Chino-shi (JP); Teruyuki KOBAYASHI, Kani-shi (JP); Takuya TORII, Komaki-shi (JP); Masahiro INOUE, Kounan-shi (JP)

(21) Appl. No.: 14/538,455

(22) Filed: Nov. 11, 2014

(30) Foreign Application Priority Data
Nov. 13, 2013 (JP) 2013-234941

(51) Int. Cl. H05K 1/02; H05K 1/11; H01B 1/02; H01G 4/12; H01G 4/008; H05K 1/18; H01G 4/30

(52) U.S. Cl. CPC H05K 1/0298; H05K 1/183; H05K 1/115; H01G 4/30; H01G 4/1227; H01G 4/008; H01B 1/026; H05K 2201/10015
USPC 174/251

(57) ABSTRACT

[Objective] To provide a multilayer wiring substrate in which, even when a core substrate is thinned, the core substrate can reliably accommodate a capacitor.

[Means for Solution] A multilayer wiring substrate 10 includes a sheetlike capacitor element 101, a resin filler 92, and via conductors 43 and 47. A sheetlike capacitor element 101 has an element main-surface 102 and an element back-surface 103, is configured such that a dielectric layer 107 is sandwiched directly between a main-surface-side electrode layer 105 exposed at the element main-surface 102 side and a back-surface-side electrode layer 106 exposed at the element back-surface 103 side, and is accommodated at least partially in an accommodation hole 90 such that a core main-surface 12 and the element main-surface 102 face the same direction. A resin filler 92 is charged into a gap between the sheetlike capacitor element 101 and an inner wall surface 91 of the accommodation hole 90. The via conductors 43 and 47 are provided in at least interlayer insulating layers 33 to 38 formed on the core main-surface 12 side, and are connected to at least the main-surface-side electrode layer 105.

### TECHNICAL FIELD

The present invention relates to a multilayer wiring substrate which includes a core substrate and a wiring laminate formed on at least a core main-surface of the core substrate.

### BACKGROUND ART

In association with recent increasing tendency toward higher operation speed and higher functionality of semiconductor integrated circuit devices (IC chips) used as, for example, microprocessors of computers, the number of terminals increases, and the pitch between the terminals tends to become narrower. Generally, a large number of terminals are disposed densely in an array on the bottom surface of an IC chip, and such a terminal group is flip-chip-connected to a terminal group on a motherboard. However, since a terminal group on the IC chip and a terminal group on the motherboard differ greatly in an inter-terminal pitch, difficulty is encountered in directly connecting the IC chip on the motherboard. Thus, usually, there is fabricated a package in which the IC chip is mounted on a multilayer wiring substrate, and the package is mounted on the motherboard. Also, in order to reduce switching noise of the IC chip and to stabilize a supply voltage for the IC chip, it is proposed that a capacitor be provided in the multilayer wiring substrate of such a package. For example, there has been conventionally proposed a multilayer wiring substrate configured such that a capacitor is embedded in a core substrate, and a build-up layer in which resin insulating layers and conductor layers are laminated is formed on each of the front and back surfaces of the core substrate. Also, there has been conventionally proposed a multilayer wiring substrate in which a build-up layer is formed such that a sheet (electrode layers and a dielectric layer) having a capacitor function is laminated (refer to, for example, Patent Documents 1 and 2).

Incidentally, in recent years, in association with tendency toward higher operation speed of IC chips, signal frequencies to be used are shifting to those in a high frequency band. In this case, wiring which runs through the core substrate (i.e., wiring for establishing electrical communication between the build-up layers formed on the front and back surfaces) becomes a source of high inductance, leading to the occurrence of transmission loss of a high-frequency signal and a circuit malfunction and thus hindering the implementation of higher operation speed. In order to solve this problem, there has been studied the fabrication of, for example, a multilayer wiring substrate having a core substrate which is thinned to a thickness of 40 μm to 50 μm. Since these wiring substrates are reduced in overall wiring length through reduction of the thickness of a core substrate, which is relatively thick, the transmission loss of a high-frequency signal is reduced, whereby an IC chip can be operated at high speed.

### PRIOR ART DOCUMENTS

### Patent Documents

[Patent Document 1] Japanese Patent Application Laid-Open (kokai) No. 2008-218966 (FIG. 1L, etc.)
[Patent Document 2] Japanese Patent Application Laid-Open (kokai) No. 2008-112815 (FIG. 2(n), etc.)

### SUMMARY OF THE INVENTION

### Problem to be Solved by the Invention

However, capacitors to be embedded in the core substrate are an MLCC (multi-layer ceramic capacitor) such as a chip capacitor, and a via-array-type capacitor having a structure in which a plurality of inner electrode layers are laminated through intervening dielectric layers, and a plurality of via conductors connected to the plurality of inner electrode layers are disposed in an array. However, since the chip capacitor and the via-array-type capacitor have a thickness of 150 μm to 550 μm and a thickness of 400 μm or more, respectively, and are thus thicker than the thinned core substrate, it is impossible to embed the capacitors in the core substrate. As in the case of the conventional technique described in Patent Documents 1 and 2, in the case where a sheet having a capacitor function is laminated to form a build-up layer, there is required a step of removing unnecessary metal portions by use of etching or the like; thus, there arises a problem such as a deterioration in dimensional accuracy of the capacitor and an increase in manufacturing cost of the capacitor.

The present invention has been conceived in view of the above problem, and an object of the invention is to provide a multilayer wiring substrate in which, even when a core substrate is thinned, the core substrate can reliably accommodate a capacitor.

### Means for Solving the Problem

Means for solving the above problem (means 1) provides a multilayer wiring substrate comprising: a core substrate having a core main-surface and a core back-surface and having an accommodation hole which opens at least at the core main-surface side; and a wiring laminate in which interlayer insulating layers and conductor layers are alternatingly laminated on at least the core main-surface, the multilayer wiring substrate being characterized by further comprising: a sheetlike capacitor element having an element main-surface and an element back-surface, configured such that a single dielectric layer is sandwiched directly between a main-surface-side electrode layer exposed at the element main-surface side and a back-surface-side electrode layer exposed at the element back-surface side, and accommodated at least partially in the accommodation hole such that the core main-surface and the element main-surface face the same direction; a resin filler charged into a gap between the sheetlike capacitor element and an inner wall surface of the accommodation hole formed in the core substrate; and a via conductor provided in at least the interlayer insulating layers of the wiring laminate on the core main-surface and connected to at least the main-surface-side electrode layer.

Thus, according to the multilayer wiring substrate of means 1 mentioned above, a capacitor to be accommodated in the accommodation hole is the relatively thin sheetlike capacitor element composed of the main-surface-side electrode layer, the back-surface-side electrode layer, and the single dielectric layer; therefore, even when the core substrate is thinned, the capacitor can be reliably accommodated in the accommodation hole. Also, since the main-surface-side electrode layer can be exposed at the entire element main-surface, the degree of freedom is enhanced with respect to the position and number of the via conductor(s) connected to the main-surface-side electrode layer. Similarly, since the back-surface-side electrode layer can be exposed at the entire element back-surface, the degree of freedom is enhanced with respect to the position and number of the via conductor(s) connected to the back-surface-side electrode layer. Furthermore, by means of the main-surface-side electrode layer being exposed at the entire element main-surface, the number of the via conductor(s) connected to the main-surface-side electrode layer can be increased, and, by means of the back-surface-side electrode layer being exposed at the entire element back-surface, the number of the via conductor(s) connected to the back-surface-side electrode layer can be increased, whereby reliability in connection of the via conductor(s) is improved. Additionally, since a connectable range for the via conductor(s) (i.e., regions where the main-surface-side electrode layer and the back-surface-side electrode layer exist) can be set to the entire element main-surface and to the entire element back-surface, even when the via conductor(s) positionally deviate in planar directions of the element main-surface and the element back-surface, the via conductor(s) can be reliably connected to the electrode layers.

The core substrate of the multilayer wiring substrate mentioned above has a plate-like shape having the core main-surface and the core back-surface, which is located opposite the core main-surface, and has the accommodation hole for accommodating the sheetlike capacitor element therein. The accommodation hole may be a nonthrough hole which opens only at the core main-surface side, or a through hole which opens at both of the core main-surface side and the core back-surface side.

No particular limitation is imposed on the material used to form the core substrate; however, a preferable core substrate is formed primarily of a polymeric material. Specific examples of a polymeric material used to form the core substrate include epoxy resin, polyimide resin, bismaleimide-triazine resin, and polyphenylene ether resin. Additionally, there may be used a composite material consisting of any one of these resins, and glass fiber (glass woven fabric or glass nonwoven fabric) or organic fiber such as polyamide fiber.

No particular limitation is imposed on the thickness of the core substrate; however, preferably, the thickness is, for example, 15 μm to 100 μm. If the thickness of the core substrate is less than 15 μm, since the core substrate becomes thin, the strength of the core substrate deteriorates, as does, in turn, the strength of the multilayer wiring substrate. On the other hand, if the thickness of the core substrate is in excess of 100 μm, wiring which runs through the core substrate becomes a source of high inductance, leading to the occurrence of transmission loss of a high-frequency signal and a circuit malfunction.

The sheetlike capacitor element has the element main-surface and the element back-surface and is accommodated in the accommodation hole such that the core main-surface and the element main-surface face the same direction. The sheetlike capacitor element may be accommodated in the accommodation hole such that the entirety thereof is accommodated or such that only a portion thereof is accommodated. In the case where the entire sheetlike capacitor element is accommodated in the accommodation hole, there can be prevented a protrusion of the sheetlike capacitor element from the opening of the accommodation hole. Therefore, the surface of the wiring laminate in contact with the core main-surface, and the surface of the wiring laminate in contact with the core back-surface, can be flat, whereby the dimensional accuracy of the wiring laminates is improved.

The sheetlike capacitor element can have any shape as viewed in plane; particularly, a polygonal shape having a plurality of sides as viewed in plane is preferred. Examples of a polygonal shape as viewed in plane include a substantially square shape as viewed in plane, a substantially triangular shape as viewed in plane, and a substantially hexagonal shape as viewed in plane; particularly, a substantially square shape, which is a general shape, as viewed in plane is preferred. A “substantially square shape as viewed in plane” is not limited to a completely square shape as viewed in plane, but encompasses a square shape having chamfered corners and a square shape having partially curved sides.

Furthermore, the sheet capacitor element is configured such that the single dielectric layer is sandwiched directly between the main-surface-side electrode layer exposed at the element main-surface side, and the back-surface-side electrode layer exposed at the element back-surface side. No particular limitation is imposed on the overall thickness of the sheetlike capacitor element; however, preferably, the overall thickness is, for example, 20 μm to 100 μm. If the overall thickness of the sheetlike capacitor element is less than 20 μm, sufficient strength fails to be secured, causing difficulty in singly handling the sheetlike capacitor element. On the other hand, if the overall thickness of the sheetlike capacitor element is in excess of 100 μm, there may be hindered the implementation of higher densification and size reduction of the multilayer wiring substrate. Also, when the sheetlike capacitor element is accommodated in the accommodation hole, the sheetlike capacitor element is apt to protrude from the opening of the accommodation hole with the resultant formation of a step between the element main-surface and the core main-surface and between the element back-surface and the core back-surface. As a result, the surface of the wiring laminate in contact with the core main-surface, and the surface of the wiring laminate in contact with the core back-surface may fail to have smoothness.

Meanwhile, examples of material used to form the main-surface-side electrode layer and the back-surface-side electrode layer include silver, gold, platinum, copper, titanium, aluminum, palladium, nickel, and tungsten; particularly, copper, which has high electrical conductivity, is preferred. In this case, since the main-surface-side electrode layer and the back-surface-side electrode layer are formed of a relatively inexpensive material, the sheetlike capacitor element can be reduced in cost. Also, since the main-surface-side electrode layer and the back-surface-side electrode layer can be adjusted in thickness by etching, by means of the main-surface-side electrode layer and the back-surface-side electrode layer being reduced in thickness by etching, the overall thickness of the sheetlike capacitor element can be reduced. Therefore, the thickness of the sheetlike capacitor element can be rendered readily compatible with the thickness of the thinned core substrate.

Preferably, the main-surface-side electrode layer and the back-surface-side electrode layer have a thickness of, for example, 1 μm to 30 μm. If the thicknesses of the main-surface-side electrode layer and the back-surface-side electrode layer are less than 1 μm, electrical reliability may fail to be secured. Also, difficulty is encountered in adjusting the thicknesses of the main-surface-side electrode layer and the back-surface-side electrode layer by etching. On the other hand, if the thicknesses of the main-surface-side electrode layer and the back-surface-side electrode layer are in excess of 30 μm, the sheetlike capacitor element becomes thick, potentially resulting in a failure to accommodate the sheetlike capacitor element in the accommodation hole. In this regard, through employment of a thickness of 1 μm to 30 μm, an increase in the thickness of the sheetlike capacitor element can be prevented while electrical reliability is secured.

The dielectric layer of the sheetlike capacitor element mentioned above is a layer which contains an inorganic substance having a high dielectric constant (e.g., dielectric ceramic) as a main component. Dielectric ceramic is a ceramic having a high dielectric constant (defined as a ceramic having a dielectric constant of 10 or more) and corresponds to, for example, a complex oxide having a perovskite-type crystal structure. A specific example of such a complex oxide is a compound composed, singly or in combination, of barium titanate, lead titanate, and strontium titanate.

Preferably, the thickness of the dielectric layer is, for example, 3 μm to 5 μm. A thin dielectric layer is favorable for implementation of high capacitance of the sheetlike capacitor element; however, if the dielectric layer becomes excessively thin to less than 3 μm, electrical insulation may fail to be secured between the main-surface-side electrode layer and the back-surface-side electrode layer. On the other hand, if the thickness of the dielectric layer exceeds 5 μm, not only is difficulty encountered in implementing high capacitance, but also the sheetlike capacitor element becomes thick and may fail to be accommodated in the accommodation hole.

The thicknesses of the main-surface-side electrode layer and the back-surface-side electrode layer may be greater than the thickness of the dielectric layer and smaller than the thickness of the core substrate. Through employment of this thickness relation, the thicknesses of the main-surface-side electrode layer and the back-surface-side electrode layer are easily secured, thereby facilitating the thinning of the main-surface-side electrode layer and the back-surface-side electrode layer by etching and, in turn, the thinning of the sheetlike capacitor element. Also, since the main-surface-side electrode layer and the back-surface-side electrode layer are thinner than the core substrate, when the sheetlike capacitor element is accommodated in the accommodation hole, there can be prevented protrusion of the sheetlike capacitor element from the opening of the accommodation hole. Therefore, the surface of the wiring laminate in contact with the core main-surface, and the surface of the wiring laminate in contact with the core back-surface can be flat, whereby the dimensional accuracy of the wiring laminates is improved.

The gap between the sheetlike capacitor element and the inner wall surface of the accommodation hole is filled with the resin filler. Material for the resin filler can be selected as appropriate in view of electrical insulation quality, resistance to heat, resistance to humidity, etc. Preferred examples of a polymeric material used to form the resin filler include epoxy resin, phenolic resin, urethane resin, silicone resin, and polyimide resin.

The wiring laminate of the multilayer wiring substrate mentioned above has a structure in which the interlayer insulating layers formed primarily of a polymeric material, and the conductor layers are alternatingly laminated on at least the core main-surface. Material for the interlayer insulating layers can be selected as appropriate in view of electrical insulation quality, resistance to heat, resistance to humidity, etc. Preferred examples of a polymeric material used to form the interlayer insulating layers include thermosetting resins, such as epoxy resin, phenolic resin, urethane resin, silicone resin, polyimide resin, bismaleimide-triazine resin, xylene resin, and polyester resin, and thermoplastic resins, such as polycarbonate resin, acrylic resin, polyacetal resin, and polypropylene resin.

The conductor layers can be formed of an electrically conductive metal material. Examples of a metal material used to form the conductor layers include copper, silver, iron, cobalt, and nickel. Particularly, the conductor layers are formed preferably of copper, which is high in electrical conductivity and is inexpensive. Also, preferably, the conductor layers are formed by plating. By doing so, the conductor layers can be formed with ease and at low cost. However, the conductor layers may be formed through application of metal paste by printing.

The via conductor connected to at least the main-surface-side electrode layer is provided in the interlayer insulating layers of the wiring laminate formed on at least the core main-surface. For example, the multilayer wiring substrate comprises, as the via conductor, one or a plurality of main-surface-side via conductors provided in the interlayer insulating layers of the wiring laminate on the core main-surface and connected to the main-surface-side electrode layer, and one or a plurality of back-surface-side via conductors provided in the interlayer insulating layers of the wiring laminate on the core back-surface and connected to the back-surface-side electrode layer. In this case, the number of the main-surface-side via conductor(s) and the number of the back-surface-side via conductor(s) may be equal to each other. By doing so, the core main-surface side (the side on which the main-surface-side via conductor(s) exist) and the core back-surface side (the side on which the back-surface-side via conductor(s) exist) become equal to each other in thermal expansion coefficient. Therefore, there can be prevented stress concentration on connections between the main-surface-side via conductor(s) and the man-surface-side electrode layer and stress concentration on connections between the back-surface-side via conductor(s) and the back-surface-side electrode layer, which could otherwise result from the difference in thermal expansion coefficient therebetween.

Furthermore, in the case where the multilayer wiring substrate comprises, as the via conductor, a plurality of main-surface-side via conductors and a plurality of back-surface-side via conductors, the plurality of main-surface-side via conductors may be connected to the main-surface-side electrode layer disposed in an outer peripheral region of the sheetlike capacitor element except that part of the main-surface-side via conductors are connected to the main-surface-side electrode layer disposed in a central region of the sheetlike capacitor element; and the plurality of back-surface-side via conductors may be connected to the back-surface-side electrode layer disposed in an outer peripheral region of the sheetlike capacitor element except that part of the back-surface-side via conductors are connected to the back-surface-side electrode layer disposed in a central region of the sheetlike capacitor element. In this case, since the main-surface-side via conductors can be connected to the outer peripheral region and the central region of the main-surface-side electrode layer, and the back-surface-side via conductors can be connected to the outer peripheral region and the central region of the back-surface-side electrode layer, the degree of freedom is enhanced with respect to the position of the via conductors.

### BRIEF DESCRIPTION OF THE DRAWINGS

FIG. 1 Schematic sectional view showing a multilayer wiring substrate according to an embodiment of the present invention.

FIG. 2 Schematic sectional view showing a sheetlike capacitor element.

FIG. 3 Schematic sectional view showing a state of connection between the sheetlike capacitor element and main-surface-side via conductors.

FIG. 4 Schematic sectional view showing a state of connection between the sheetlike capacitor element and back-surface-side via conductors.

FIG. 5 Explanatory view showing a step of forming through hole conductors, filler resin, and conductor layers, and an accommodation hole forming step.

FIG. 6 Explanatory view showing an accommodation step.

FIG. 7 Explanatory view showing a filling step.

FIG. 8 Explanatory view showing a step of forming via holes.

FIG. 9 Explanatory view showing a step of forming conductor layers and via conductors.

FIG. 10 View for explaining a problem involved in a chip capacitor.

FIG. 11 Sectional view taken along line A-A of FIG. 10.

FIG. 12 Schematic sectional view showing a sheetlike capacitor element according to the other embodiment of the present invention.

FIG. 13 Schematic sectional view showing a state of connection between the sheetlike capacitor element and main-surface-side via conductors in the other embodiment.

### MODES FOR CARRYING OUT THE INVENTION

A multilayer wiring substrate according to an embodiment of the present invention will next be described in detail with reference to the drawings.

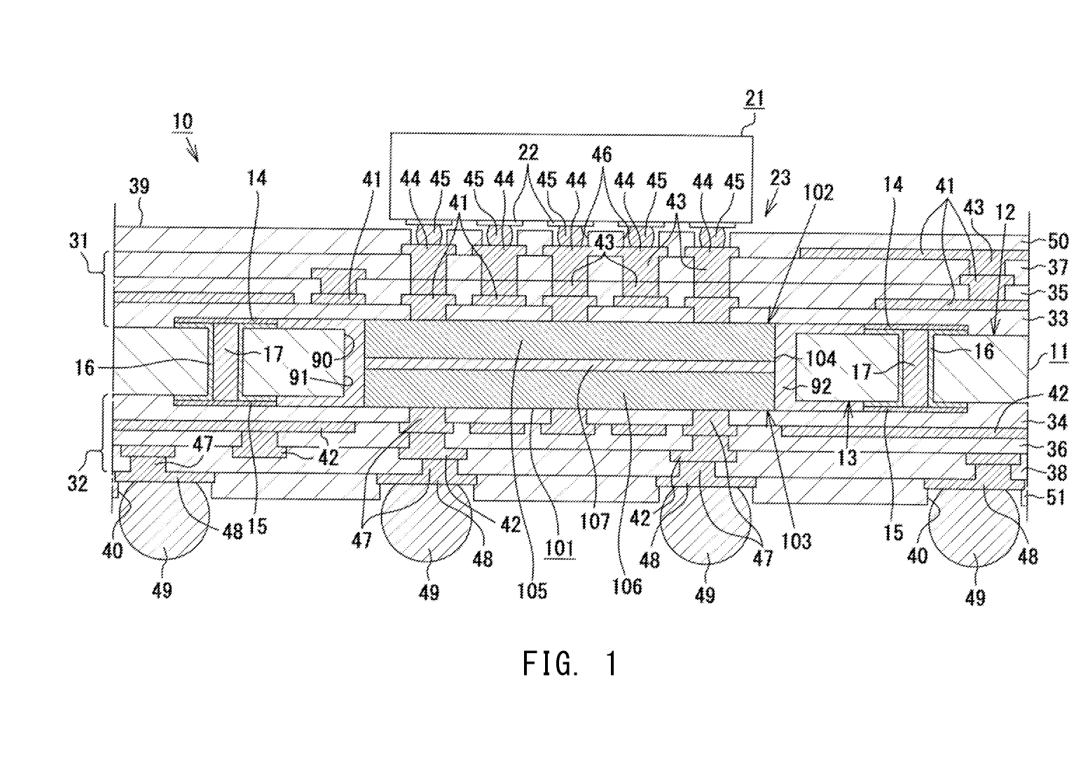

As shown in FIG. 1, a multilayer wiring substrate 10 of the present embodiment is a wiring substrate for mounting an IC chip thereon. The multilayer wiring substrate 10 includes a substantially square plate-like core substrate 11, a main-surface-side build-up layer 31 (a wiring laminate) formed on a core main-surface 12 (the upper surface in FIG. 1) of the core substrate 11, and a back-surface-side build-up layer 32 (a wiring laminate) formed on a core back-surface 13 (the lower surface in FIG. 1) of the core substrate 11.

The core substrate 11 of the present embodiment has a square shape as viewed in plane, measuring 25 mm length×25 mm width. Also, the core substrate 11 has a thickness of 15 μm to 100 μm (46 μm in the present embodiment). The core substrate 11 is formed of a thermosetting resin (epoxy resin) and has a thermal expansion coefficient of about 10 ppm/° C. to 30 ppm/° C. (specifically, 18 ppm/° C.) with respect to a planar direction (XY direction). The thermal expansion coefficient of the core substrate 11 is a mean value of thermal expansion coefficient values measured in a temperature range of 0° C. to the glass transition temperature (Tg).

As shown in FIG. 1, the core substrate 11 has a plurality of through hole conductors 16 formed therethrough between the core main-surface 12 and the core back-surface 13. The through hole conductors 16 connect the core main-surface 12 side and the core back-surface 13 side of the core substrate 11 and establish electrical communication therebetween. The interiors of the through hole conductors 16 are filled with a filler resin 17 such as epoxy resin. A main-surface-side conductor layer 14 (thickness 2 μm) made of copper is formed through patterning on the core main-surface 12 of the core substrate 11; similarly, a back-surface-side conductor layer 15 (thickness 2 μm) made of copper is formed through patterning on the core back-surface 13 of the core substrate 11. The conductor layers 14 and 15 are electrically connected to the through hole conductors 16. Furthermore, the core substrate 11 has a single accommodation hole 90 which has a square shape as viewed in plane and opens at a central portion of the core main-surface 12 and at a central portion of the core back-surface 13. That is, the accommodation hole 90 is a through hole.

A sheetlike capacitor element 101 is accommodated in the accommodation hole 90 in an embedded condition. The sheetlike capacitor element 101 is accommodated such that the core main-surface 12 of the core substrate 11 and an element main-surface 102 (the upper surface in FIG. 1) face the same direction and such that the core back-surface 13 and an element back-surface 103 (the lower surface in FIG. 1) face the same direction. The sheetlike capacitor element 101 has a square shape as viewed in plane, measuring 3 mm square to 5 mm square (5 mm square in the present embodiment). The sheetlike capacitor element 101 has an overall thickness of 20 μm to 100 μm (50 μm in the present embodiment). That is, the thickness of the sheetlike capacitor element 101 is equal to the total of the thickness (46 μm) of the core substrate 11, the thickness (2 μm) of the main-surface-side conductor layer 14, and the thickness (2 μm) of the back-surface-side conductor layer 15.

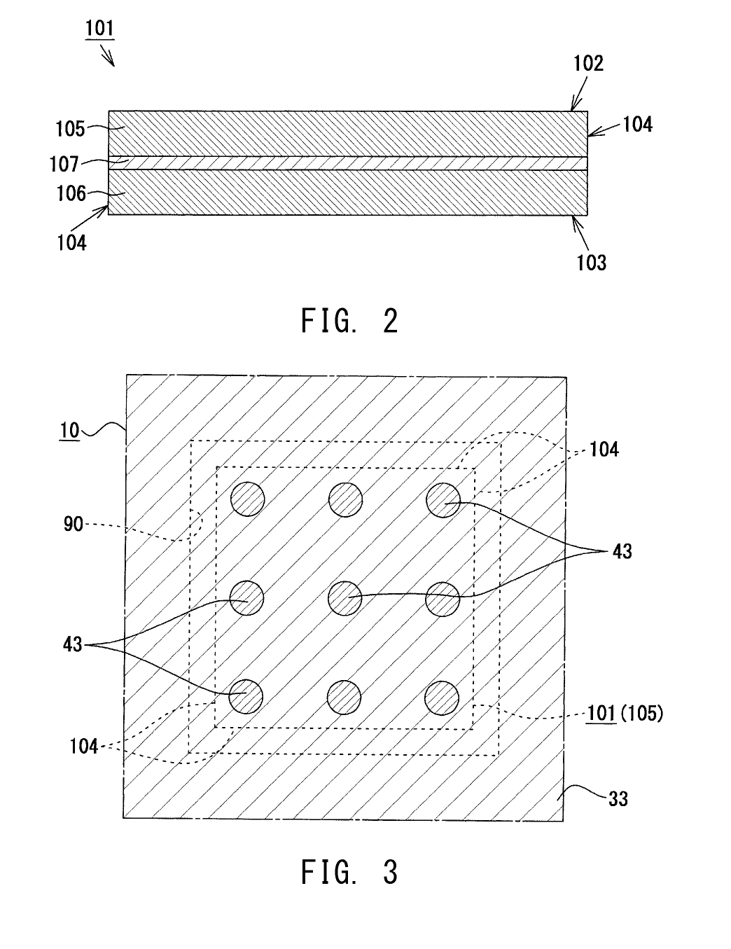

As shown in FIGS. 1 and 2, the sheetlike capacitor element 101 has the single element main-surface 102 (the upper surface in FIG. 1), the single element back-surface 103 (the lower surface in FIG. 1), and four element side-surfaces 104. Also, the sheetlike capacitor element 101 has a structure in which a single dielectric layer 107 formed of barium titanate is sandwiched directly between the main-surface-side electrode layer 105 formed of copper and the back-surface-side electrode layer 106 formed of copper. The main-surface-side electrode layer 105 is exposed at the entire element main-surface 102, and the back-surface-side electrode layer 106 is exposed at the entire element back-surface 103. In the present embodiment, the main-surface-side electrode layer 105 and the back-surface-side electrode layer 106 have a thickness of 1 μm to 30 μm (20 μm in the present embodiment), and the dielectric layer 107 has a thickness of 3 μm to 5 μm (5 μm in the present embodiment). That is, the thicknesses of the main-surface-side electrode layer 105 and the back-surface-side electrode layer 106 are greater than the thickness of the dielectric layer 107 and smaller than the thickness (46 μm) of the core substrate 11. The dielectric layer 107 has a thermal expansion coefficient of less than 15 ppm/° C., specifically about 12 ppm/° C. to 13 ppm/° C. The thermal expansion coefficient of the dielectric layer 107 is a mean value of thermal expansion coefficient values measured in a temperature range of 30° C. to 250° C.

When the thus-configured sheetlike capacitor element 101 is energized to apply a predetermined voltage between the main-surface-side electrode layer 105 and the back-surface-side electrode layer 106, positive charges are accumulated in one electrode layer, and negative charges are accumulated in the other electrode layer. As a result, the sheetlike capacitor element 101 functions as a capacitor.

As shown in FIG. 1, a gap between an inner wall surface 91 of the accommodation hole 90 and the element side-surfaces 104 of the sheetlike capacitor element 101 is filled with a resin filler 92 formed of a polymeric material (in the present embodiment, epoxy resin, which is a thermosetting resin). The resin filler 92 has a function of fixing the sheetlike capacitor element 101 to the core substrate 11.

As shown in FIG. 1, the main-surface-side build-up layer 31 has a structure in which three interlayer insulating layers 33, 35, and 37 formed of a thermosetting resin (epoxy resin) and conductor layers 41 formed of copper are alternatingly laminated. In the present embodiment, the main-surface-side build-up layer 31 has a thermal expansion coefficient of about 10 ppm/° C. to 60 ppm/° C. (specifically, about 20 ppm/° C.). The thermal expansion coefficient of the main-surface-side build-up layer 31 is a mean value of thermal expansion coefficient values measured in a temperature range of 30° C. to the glass transition temperature (Tg). Also, a plurality of main-surface-side via conductors 43 formed by copper plating and each having a circular shape as viewed in plane exist in the interlayer insulating layers 33, 35, and 37.

As shown in FIG. 3, in the present embodiment, part (nine in the present embodiment) of the main-surface-side via conductors 43 provided in the interlayer insulating layer 33 are connected to the main-surface-side electrode layer 105 of the sheetlike capacitor element 101. More specifically, the main-surface-side via conductors 43 connected to the main-surface-side electrode layer 105 are disposed in an array. Most (eight) of the main-surface-side via conductors 43 are connected to the main-surface-side electrode layer 105 in a region located at an outer peripheral portion of the sheetlike capacitor element 101, and part (one) of the main-surface-side via conductors 43 are connected to the main-surface-side electrode layer 105 in a region located at a central portion of the sheetlike capacitor element 101.

As shown in FIG. 1, on the surface of the interlayer insulating layer 37, the conductor layer 41 is formed, and a plurality of terminal pads 44 are formed in an array. The terminal pads 44 in the present embodiment are so-called C4 pads (Controlled Collapsed Chip Connection pads). Furthermore, almost entire surface of the interlayer insulating layer 37 is covered with a solder resist layer 50. The solder resist layer 50 has openings 46 formed therein at predetermined positions for exposing the terminal pads 44. A plurality of solder bumps 45 are disposed on the surfaces of the terminal pads 44, respectively.

The solder bumps 45 are electrically connected to corresponding surface connection terminals 22 of an IC chip (semiconductor integrated circuit device). The IC chip 21 in the present embodiment is a plate-like article having a square shape as viewed in plane and measuring 12.0 mm length×12.0 mm width×0.9 mm thickness and is formed of silicon having a thermal expansion coefficient of about 3 ppm/° C. to 4 ppm/° C. (specifically, about 3.5 ppm/° C.). A region where the terminal pads 44 and the solder bumps 45 exist is an IC chip mounting region 23 where the IC chip 21 can be mounted. The IC chip mounting region 23 is provided on a surface 39 of the solder resist layer 50.

As shown in FIG. 1, the back-surface-side build-up layer 32 has substantially the same structure as that of the main-surface-side build-up layer 31 mentioned above. Specifically, the back-surface-side build-up layer 32 has a thermal expansion coefficient of about 10 ppm/° C. to 60 ppm/° C. (specifically, about 20 ppm/° C.) and has a structure in which conductor layers 42 and three interlayer insulating layers 34, 36, and 38 formed of a thermosetting resin (epoxy resin) are alternatingly laminated. Also, a plurality of back-surface-side via conductors 47 formed by copper plating and each having a circular shape as viewed in plane exist in the interlayer insulating layers 34, 36, and 38. That is, in the present embodiment, the main-surface-side via conductors 43 and the back-surface-side via conductors 47 have the same shape as viewed in plane.

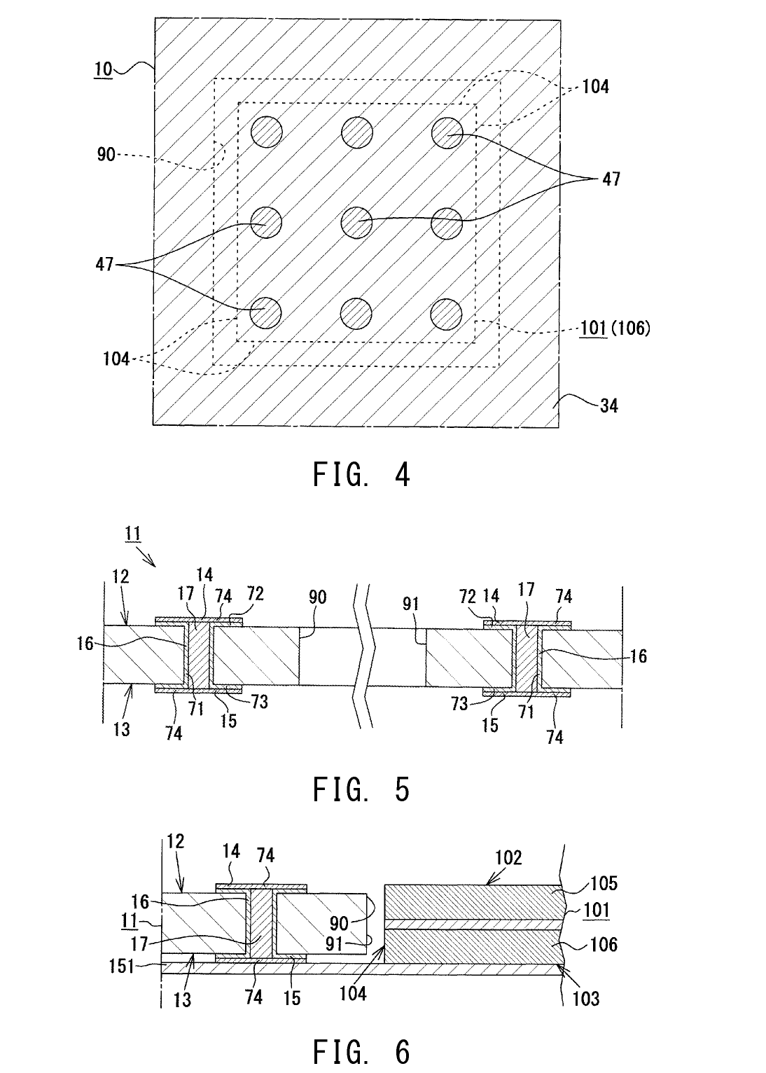

As shown in FIG. 4, in the present embodiment, part (nine) of the back-surface-side via conductors 47 provided in the interlayer insulating layer 34 are connected to the back-surface-side electrode layer 106 of the sheetlike capacitor element 101. That is, in the present embodiment, the number of the main-surface-side via conductors 43 connected to the main-surface-side electrode layer 105 and the number of the back-surface-side via conductors 47 connected to the back-surface-side electrode layer 106 are equal to each other. More specifically, the back-surface-side via conductors 47 connected to the back-surface-side electrode layer 106 are disposed in an array. Most (eight) of the back-surface-side via conductors 47 are connected to the back-surface-side electrode layer 106 in a region located at an outer peripheral portion of the sheetlike capacitor element 101, and part (one) of the back-surface-side via conductors 47 are connected to the back-surface-side electrode layer 106 in a region located at a central portion of the sheetlike capacitor element 101.

As shown in FIG. 1, a plurality of pads 48 which are electrically connected to the conductor layer 42 through the back-surface-side via conductors 47, respectively, are formed in a lattice arrangement on the lower surface of the third interlayer insulating layer 38. Also, the lower surface of the interlayer insulating layer 38 is almost entirely covered with a solder resist layer 51. The solder resist layer 51 has openings 40 formed therein at predetermined positions for exposing the pads 48. A plurality of solder bumps 49 for establishing electrical connection to an unillustrated motherboard are disposed on the surfaces of the pads 48, respectively. By means of the solder bumps 49, the multilayer wiring substrate 10 shown in FIG. 1 is mounted on the unillustrated motherboard.

Next, a method of manufacturing the multilayer wiring substrate 10 of the present embodiment will be described.

First, in a core substrate preparation step, an intermediate product of the core substrate 11 is manufactured by a conventionally known method. Specifically, there is prepared a copper clad laminate (not shown) in which copper foils are affixed on respective opposite sides of a base material measuring 400 mm length×400 mm width×46 μm thickness, thereby yielding an intermediate product of the core substrate 11. Notably, the intermediate product of the core substrate 11 is a multi-piece-array core substrate configured such that a plurality of regions which are to become individual core substrates 11 are arrayed in columns and rows as viewed in plane.

Then, the through holes where the respective through hole conductors 16 are to be formed are formed in the core substrate 11 (the copper clad laminate) at predetermined positions through drilling by use of a drilling machine. Next, electroless copper plating is performed on the entire surface of the core substrate 11 which encompasses the inner wall surfaces of the through holes, the core main-surface 12, and the core back-surface 13, followed by copper electroplating. As a result, plating layers 71 which are to become the through hole conductors 16 are formed on the inner wall surfaces of the through holes, respectively (see FIG. 5). Furthermore, a plating layer 72 which is to become the main-surface-side conductor layer 14 is formed on the core main-surface 12, and a plating layer 73 which is to become the back-surface-side conductor layer 15 is formed on the core back-surface 13 (see FIG. 5). Subsequently, the hollows of the plating layers 71, which are to become the through hole conductors 16, are filled with an electrically insulative material (epoxy resin), thereby forming the filler resin 17 (see FIG. 5).

Then, by means of electroless copper plating being performed according to a conventionally known method, a plating layer 74 (see FIG. 5) is formed on the surfaces of the plating layers 72 and 73. Next, the plating layer 74 is etched by, for example, a subtractive process for patterning. Specifically, dry films are laminated respectively on the plating layer 74 on the core main-surface 12 side and on the plating layer 74 on the core back-surface 13 side; then, the dry films are subjected to exposure and development, thereby forming the dry films into respectively predetermined patterns. In this condition, unnecessary portions of the plating layers 74 are etched away; subsequently, the dry films are removed. As a result, the main-surface-side conductor layer 14 is formed on the core main-surface 12, and the back-surface-side conductor layer 15 is formed on the core back-surface 13 (see FIG. 5). At this time, portions of the plating layer 74 on the core main-surface 12 side become a covering plating layer which covers the end surfaces of the through hole conductors 16 on the core main-surface 12 side, and portions of the plating layer 74 on the core back-surface 13 side become a covering plating layer which covers the end surfaces of the through hole conductors 16 on the core back-surface 13 side.

In a subsequent accommodation hole forming step, by use of a router, the accommodation hole 90 is formed in the core substrate 11 (the copper clad laminate) at a predetermined position (see FIG. 5). The accommodation hole 90 is a hole having, as viewed in plane, a substantially square shape, 7 mm on a side, curved at four corners.

In a sheetlike capacitor element preparation step, the sheetlike capacitor element 101 is manufactured by a conventionally well known method.

The sheetlike capacitor element 101 is manufactured in the following manner. First, dielectric slurry is prepared through the following procedure. Barium titanate powder (dielectric powder) having an average particle size of 0.7 μm, a mixed solvent of ethanol and toluene, dispersant, and plasticizer are wet-mixed in a pot; and, at a sufficiently mixed point of time, an organic binder is added to the mixture, followed by further mixing. As a result, a starting material for forming a dielectric green sheet is yielded. At this time, by means of appropriately changing the mixing ration of the components, the dielectric slurry is adjusted to a viscosity of about 0.5 Pa·s (viscosity in one-minute value measured at 25° C. by Viscotester VT-04, a viscometer manufactured by RION Co., Ltd., by use of No. 1 rotor at 62.5 rpm). Next, by use of the dielectric slurry, the dielectric green sheet is formed as follows. A roll of PET film having a predetermined width is prepared; then, the roll is mounted in a casting apparatus at a feed side, and the dielectric slurry is cast (applied) thinly at a uniform thickness on the upper surface of the PET film by a conventionally well known method, such as the doctor blade method or lip coating. Subsequently, the dielectric slurry cast on the sheet is heated and dried by a heater disposed between the feed side and a take-up side of the casting apparatus, thereby yielding a dielectric green sheet (a green dielectric layer which is to become the dielectric layer 107) having a thickness of 5 μm.

Then, by use of a punching die or the like, the dielectric green sheet is cut into pieces each measuring 5 mm square. At this stage, since the dielectric green sheet is not hardened, punching can be performed relatively easily, and the occurrence of cracking can be prevented.

Next, the dielectric green sheet mentioned above is debindered at 250° C. for 10 hours in the atmosphere and is then fired at 1,260° C. for a predetermined period of time in a reducing atmosphere. As a result, barium titanate is heated and sintered, thereby yielding the dielectric layer 107 having a thickness of 5 μm. Next, electroless copper plating (about a thickness of 20 μm) is performed on the main surface and back surface of the yielded dielectric layer 107. As a result, the main-surface-side electrode layer 105 is formed on the main surface of the dielectric layer 107, and the back-surface-side electrode layer 106 is formed on the back surface of the dielectric layer 107, thereby completing the sheetlike capacitor element 101.

In a subsequent accommodation step, an opening of the accommodation hole 90 on the core back-surface 13 side is sealed by means of a removable adhesive tape 151 (see FIG. 6). The adhesive tape 151 is supported on a support table (not shown). Next, by use of a mounting apparatus (product of Yamaha Motor Co., Ltd.), the sheetlike capacitor element 101 is accommodated in the accommodation hole 90 such that the core main-surface 12 and the element main-surface 102 face the same direction, whereas the core back-surface 13 and the element back-surface 103 face the same direction (see FIG. 6). At this time, the element back-surface 103 of the sheetlike capacitor element 101 is affixed to the adhesive layer of the adhesive tape 151 for temporary fixation.

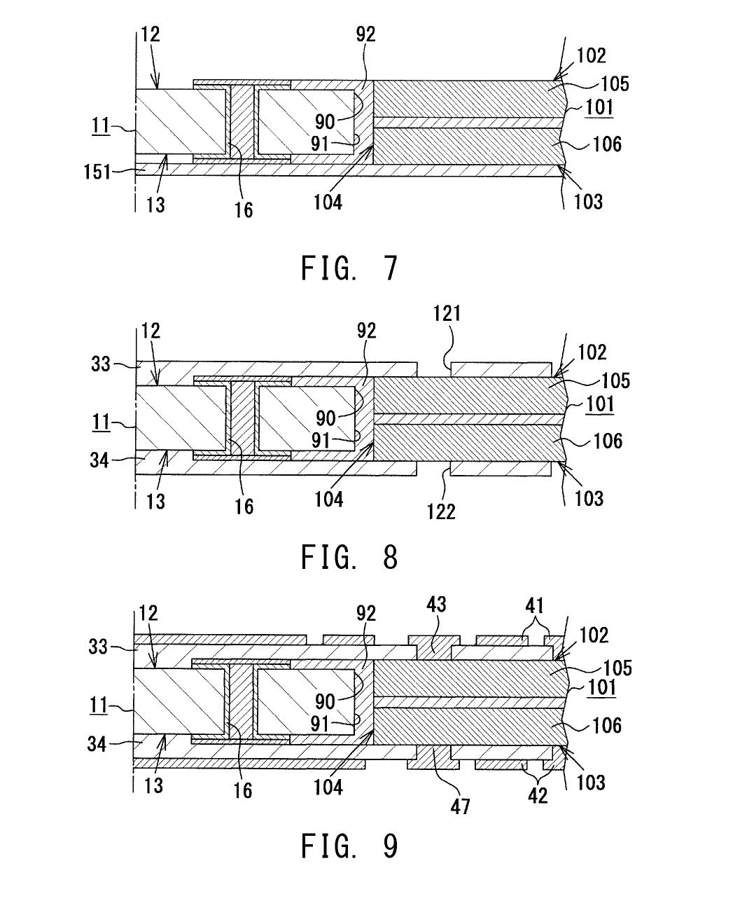

In a subsequent filling step, by use of a dispenser (product of Asymtek), a resin filler 92 (product of NAMICS CORPORATION) formed of a thermosetting resin is charged into a gap between the inner wall surface 91 of the accommodation hole 90 and the element side-surfaces 104 of the sheetlike capacitor element 101 (see FIG. 7). In a subsequent fixing step, the resin filler 92 is cured to fix the sheetlike capacitor element 101 in the accommodation hole 90. After the fixing step, the adhesive tape 151 is removed. Subsequently, the core main-surface 12, the core back-surface 13, etc., of the core substrate 11 are roughened.

Next, on the basis of a conventionally well known method, the main-surface-side build-up layer 31 is formed on the core main-surface 12, and the back-surface-side build-up layer 32 is formed on the core back-surface 13. Specifically, first, a thermosetting epoxy resin is affixed to the core main-surface 12 and the element main-surface 102, thereby forming the interlayer insulating layer 33 (see FIG. 8). Also, the thermosetting epoxy resin is affixed to the core back-surface 13 and the element back-surface 103, thereby forming the interlayer insulating layer 34 (see FIG. 8).

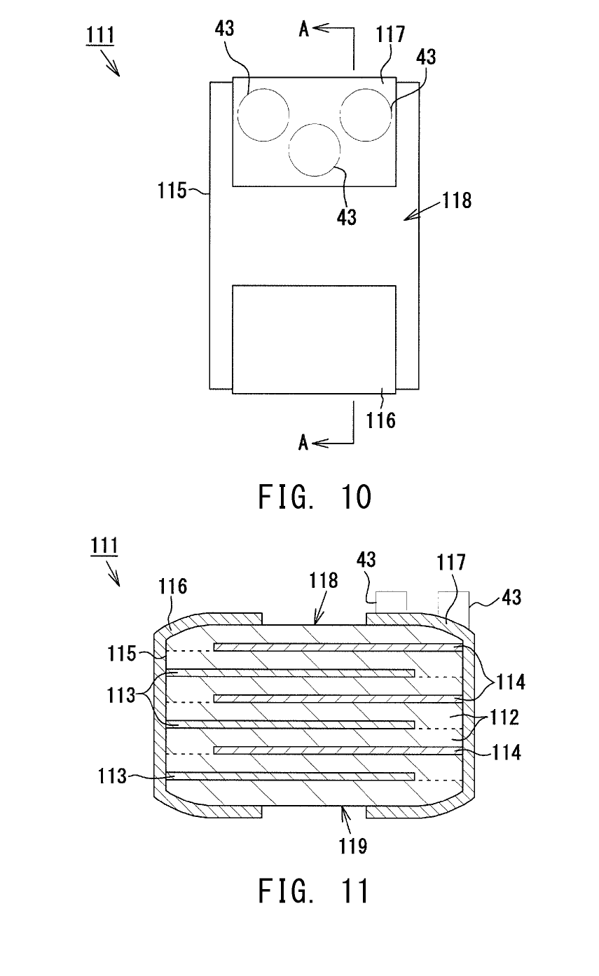

Furthermore, by use of YAG laser or carbon dioxide gas laser, laser drilling is performed to form via holes 121 at positions where the main-surface-side via conductors 43 are to be formed, as well as via holes 122 at positions where the back-surface-side via conductors 47 are to be formed (see FIG. 8). Specifically, the via holes 121 are formed through the interlayer insulating layer 33 to expose the surface (element main-surface 102) of the main-surface-side electrode layer 105 of the sheetlike capacitor element 101. Also, the via holes 122 are formed through the interlayer insulating layer 34 to expose the surface (element back-surface 103) of the back-surface-side electrode layer 106 of the sheetlike capacitor element 101. Then, electroless copper plating is performed on the surfaces of the interlayer insulating layers 33 and 34 and on the inner surfaces of the via holes 121 and 122; subsequently, etching resist is formed, followed by copper electroplating. Furthermore, the etching resist is removed, followed by soft etching. As a result, the conductor layer 41 is formed in a predetermined pattern on the interlayer insulating layer 33, and the conductor layer 42 is formed in a predetermined pattern on the interlayer insulating layer 34 (see FIG. 9). At the same time, the via conductors 43 and 47 are formed in the via holes 121 and 122, respectively.

Next, a thermosetting epoxy resin is affixed onto the interlayer insulating layer 33; then, laser-drilling is performed so as to form the interlayer insulating layer 35 having via holes (not shown) where the main-surface-side via conductors 43 are to be formed. Also, the thermosetting epoxy resin is affixed onto the interlayer insulating layer 34; then, laser-drilling is performed so as to form the interlayer insulating layer 36 having via holes (not shown) where the back-surface-side via conductors 47 are to be formed. Next, electroless copper plating is performed on the surfaces of the interlayer insulating layers 35 and 36 and on the inner surfaces of the via holes; subsequently, etching resist is formed, followed by copper electroplating. Furthermore, the etching resist is removed, followed by soft etching. As a result, the via conductors 43 and 47 are formed in the respective via holes, and the conductor layers 41 and 42 are formed in respectively predetermined patterns on the resin insulating layers 35 and 36, respectively.

Next, the thermosetting epoxy resin is affixed onto the interlayer insulating layers 35 and 36; then, laser-drilling is performed so as to form the interlayer insulating layers 37 and 38 having via holes (not shown) where the via conductors 43 and 47 are to be formed respectively. Next, according to a publicly known method, copper electroplating is performed to form the via conductors 43 and 47 in the respective via holes. At the same time, the terminal pads 44 are formed on the interlayer insulating layer 37, and the pads 48 are formed on the interlayer insulating layer 38.

Next, a photosensitive epoxy resin is applied onto the interlayer insulating layers 37 and 38, thereby forming the solder resist layers 50 and 51, respectively. Next, the solder resist layers 50 and 51 on which respectively predetermined masks are disposed are subjected to exposure and development, thereby forming the openings 46 and 40, respectively, in the solder resist layers 50 and 51. Furthermore, the solder bumps 45 are formed on the respective terminal pads 44, and the solder bumps 49 are formed on the respective pads 48. Notably, the wiring substrate in this condition is a multi-piece-array wiring substrate configured such that a plurality of product regions which are to become individual multilayer wiring substrates 10 are arrayed in columns and rows as viewed in plane. When the multi-piece-array wiring substrate is divided, a large number of individual products; i.e., the multilayer wiring substrates 10 is obtained at the same time.

Next, the IC chip 21 is mounted on the IC chip mounting region 23 of the main-surface-side build-up layer 31 of the multilayer wiring substrate 10. At this time, the surface connection terminals 22 of the IC chip 21 are aligned with the corresponding solder bumps 45. The solder bumps 45 are heated to a temperature of 220° C. to 240° C. so as to be reflowed, whereby the solder bumps 45 are joined to the corresponding surface connection terminals 22; accordingly, the multilayer wiring substrate 10 and the IC chip 21 are electrically connected to each other. As a result, the IC chip 21 is mounted in the IC chip mounting region 23 (see FIG. 1).

Therefore, the present embodiment yields the following effects.

(1) According to the multilayer wiring substrate 10 of the present embodiment, a capacitor to be accommodated in the accommodation hole 90 is the relatively thin sheetlike capacitor element 101 composed of the main-surface-side electrode layer 105, the back-surface-side electrode layer 106, and the single dielectric layer 107. Thus, in the multilayer wiring substrate 10 of the present embodiment in which the core substrate 11 is thinned, the capacitor can be reliably accommodated in the accommodation hole 90.

Also, since the main-surface-side electrode layer 105 is exposed at the entire element main-surface 102, the degree of freedom is enhanced with respect to the position and number of the main-surface-side via conductors 43 connected to the main-surface-side electrode layer 105. Similarly, since the back-surface-side electrode layer 106 is exposed at the entire element back-surface 103, the degree of freedom is enhanced with respect to the position and number of the back-surface-side via conductors 47 connected to the back-surface-side electrode layer 106. Furthermore, by means of the main-surface-side electrode layer 105 being exposed at the entire element main-surface 102, the number of the main-surface-side via conductors 43 connected to the main-surface-side electrode layer 105 can be increased, and, by means of the back-surface-side electrode layer 106 being exposed at the entire element back-surface 103, the number of the back-surface-side via conductors connected to the back-surface-side electrode layer 106 can be increased, whereby reliability in connection of the via conductors 43 and 47 is improved. Additionally, a connectable range for the main-surface-side via conductors 43 (i.e., a region where the main-surface-side electrode layer 105 exists) can be set to the entire element main-surface 102, and a connectable range for the back-surface-side via conductors 47 (i.e., a region where the back-surface-side electrode layer 106 exists) can be set to the entire element back-surface 103. Thus, even when the via conductors 43 and 47 positionally deviate in planar directions of the element main-surface 102 and the element back-surface 103, the via conductors 43 and 47 can be reliably connected to the electrode layers 105 and 106, respectively.

(2) In the present embodiment, the sheetlike capacitor element 101 is disposed immediately under the IC chip 21 mounted in the IC chip mounting region 23. Thus, wiring which connects the sheetlike capacitor element 101 and the IC chip 21 becomes short, thereby preventing an increase in an inductance component of the wiring. Therefore, switching noise of the IC chip 21 caused by the sheetlike capacitor element 101 can be reliably reduced, and a supply voltage can be reliably stabilized. Also, since noise which enters between the IC chip 21 and the sheetlike capacitor element 101 can be restrained to very low level, high reliability is provided without occurrence of malfunction and the like.

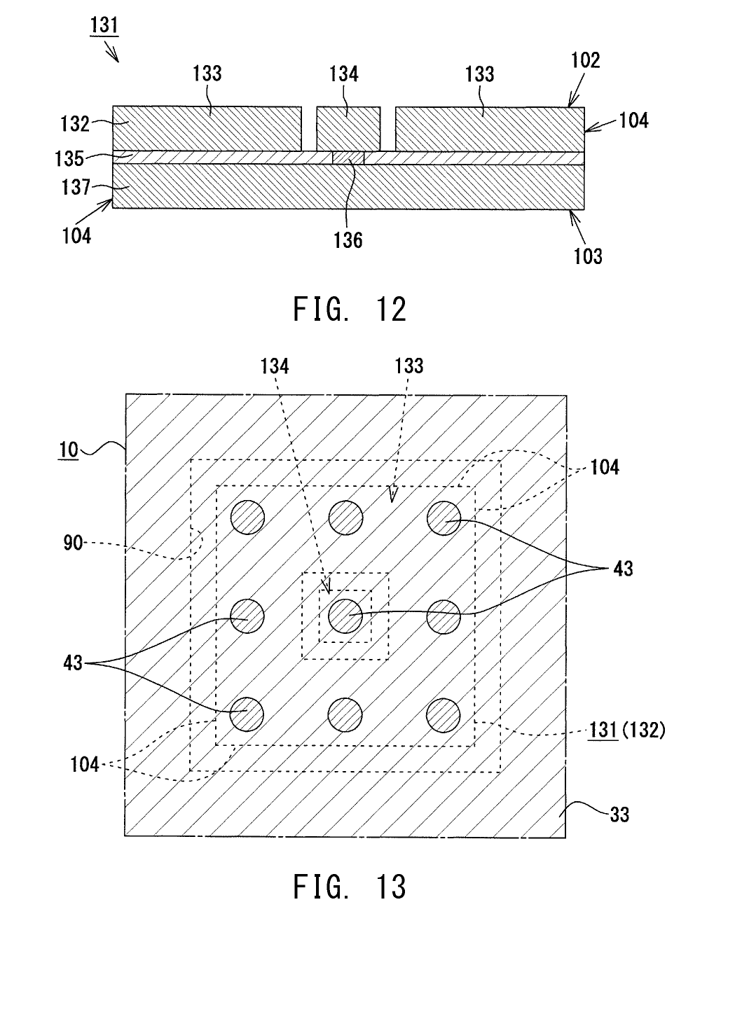

(3) Incidentally, it is conceived that, instead of accommodating the sheetlike capacitor element 101 in the accommodation hole 90 of the core substrate 11, a chip capacitor 111 shown in FIGS. 10 and 11 is accommodated in the accommodation hole 90. The chip capacitor 111 includes a ceramic sintered member 115 in which inner power-supply electrode layers 113 and inner grounding electrode layers 114 are alternatingly laminated with ceramic dielectric layers 112 intervening therebetween. Also, the ceramic sintered member 115 has a power-supply electrode 116 and a grounding electrode 117 provided on two mutually facing side surfaces thereof. The capacitor-main-surface-side end portion and capacitor-back-surface-side end portion of the power-supply electrode 116 protrude in the same direction and are located on a capacitor main-surface 118 and a capacitor back-surface 119, respectively. Similarly, the capacitor-main-surface-side end portion and capacitor-back-surface-side end portion of the grounding electrode 117 protrude in the same direction and are located on the capacitor main-surface 118 and the capacitor back-surface 119, respectively. Furthermore, the power-supply electrode 116 is connected to the plurality of inner power-supply electrode layers 113, and the grounding electrode 117 is connected to the plurality of inner grounding electrode layers 114.

However, since an outer peripheral portion of the chip capacitor 111 is usually curved (see FIG. 11), difficulty is encountered in connecting the via conductors 43 and 47 to the curved portions. Also, since the capacitor-main-surface-side end portions of the electrodes 116 and 117 are exposed at only a portion of the capacitor main-surface 118, only a small number (herein, three) of the main-surface-side via conductors 43 can be connected to the capacitor-main-surface-side end portions of the electrodes 116 and 117 (see FIG. 10). Similarly, since the capacitor-back-surface-side end portions of the electrodes 116 and 117 are exposed at only a portion of the capacitor back-surface 119, only a small number of the back-surface-side via conductors 47 can be connected to the capacitor-back-surface-side end portions.

Thus, in the present embodiment, the sheetlike capacitor element 101 is accommodated in the accommodation hole 90 of the core substrate 11. In this case, since an outer peripheral portion of the sheetlike capacitor element 101 is not curved, the main-surface-side via conductors 43 can be connected to an outer peripheral portion of the main-surface-side electrode layer 105, and the back-surface-side via conductors 47 can be connected to an outer peripheral portion of the back-surface-side electrode layer 106. Also, since the main-surface-side electrode layer 105 is exposed at the entire element main-surface 102, and the back-surface-side electrode layer 106 is exposed at the entire element back-surface 103, a large number of the via conductors 43 and 47 can be connected to the electrode layers 105 and 106, respectively.

The embodiment described above may be modified as follows.
In the embodiment described above, the number of the main-surface-side via conductors 43 (nine pieces) connected to the main-surface-side electrode layer 105 of the sheetlike capacitor element 101 and the number of the back-surface-side via conductors 47 (nine pieces) connected to the back-surface-side electrode layer 106 of the sheetlike capacitor element 101 are equal to each other. However, the number of the main-surface-side via conductors 43 connected to the main-surface-side electrode layer 105 and the number of the back-surface-side via conductors 47 connected to the back-surface-side electrode layer 106 may differ from each other.
In the embodiment described above, the main-surface-side via conductors 43 connected to the main-surface-side electrode layer 105 and the back-surface-side via conductors 47 connected to the back-surface-side electrode layer 106 are disposed in an array, but may be disposed in a different arrangement. For example, the via conductors 43 and 47 may be disposed at four corners of the electrode layers 105 and 106, respectively, or only a single via conductor 43 and only a single via conductor 47 may be disposed at central portions of the electrode layers 105 and 106, respectively. The main-surface-side via conductors 43 connected to the main-surface-side electrode layer 105 and the back-surface-side via conductors 47 connected to the back-surface-side electrode layer 106 may differ in disposition from each other.
In the embodiment described above, the electrode layers 105 and 106 of the sheetlike capacitor element 101 are in a plain pattern (solid pattern); however, the electrode layers 105 and 106 may be patterned differently. For example, as shown in a sheetlike capacitor element 131 of FIGS. 12 and 13, a main-surface-side electrode layer 132 may be divided into an annularly square outer-peripheral electrode layer 133, which is a main-surface-side electrode layer disposed in an outer peripheral region of the sheetlike capacitor element 131, and a square central electrode layer 134, which is a main-surface-side electrode layer disposed in a central region of the sheetlike capacitor element 131. The main-surface-side electrode layer 132 is electrically connected to a back-surface-side electrode layer 137 through a via conductor 136 provided in a dielectric layer 135. In this case, the main-surface-side via conductors 43 are connected to the outer-peripheral electrode layer 133 except that part (herein, one) of the main-surface-side via conductors 43 are connected to the central electrode layer 134.

Instead of dividing the main-surface-side electrode layer 132 into the outer-peripheral electrode layer 133 and the central electrode layer 134, the back-surface-side electrode layer 137 may be divided into an outer-peripheral electrode layer, which is a back-surface-side electrode layer disposed in an outer peripheral region of the sheetlike capacitor element, and a central electrode layer, which is a back-surface-side electrode layer disposed in a central region of the sheetlike capacitor element. In this case, the back-surface-side via conductors 47 are connected to the outer-peripheral electrode layer except that part of the back-surface-side via conductors 47 are connected to the central electrode layer. Also, the main-surface-side electrode layer 132 may be divided into the outer-peripheral electrode layer 133 and the central electrode layer 134, and the back-surface-side electrode layer 137 may be divided into the outer-peripheral electrode layer and the central electrode layer.
In the embodiment described above, only the single sheetlike capacitor element 101 is accommodated in the accommodation hole 90; however, two or more sheetlike capacitor elements 101 may be accommodated.

Next, technical ideas that the embodiments described above implement are enumerated below.

(1) In means 1 mentioned above, the multilayer wiring substrate is characterized by comprising, as the via conductor, one or a plurality of main-surface-side via conductors provided in the interlayer insulating layers of the wiring laminate on the core main-surface and connected to the main-surface-side electrode layer, and one or a plurality of back-surface-side via conductors provided in the interlayer insulating layers of the wiring laminate on the core back-surface and connected to the back-surface-side electrode layer, and characterized in that the main-surface-side via conductors and the back-surface-side via conductors have the same shape as viewed in plane.

(2) In means 1 mentioned above, the multilayer wiring substrate is characterized in that: the main-surface-side conductor layer is formed on the core main-surface; the back-surface-side conductor layer is formed on the core back-surface; and the thickness of the sheetlike capacitor element is the total of the thickness of the core substrate, the thickness of the main-surface-side conductor layer, and the thickness of the back-surface-side conductor layer.

(3) In means 1 mentioned above, the multilayer wiring substrate is characterized by comprising, as the via conductor, a plurality of main-surface-side via conductors provided in the interlayer insulating layers of the wiring laminate on the core main-surface and connected to the main-surface-side electrode layer, and a plurality of back-surface-side via conductors provided in the interlayer insulating layers of the wiring laminate on the core back-surface and connected to the back-surface-side electrode layer, and characterized in that the plurality of main-surface-side via conductors are connected to the main-surface-side electrode layer disposed in an outer peripheral region of the sheetlike capacitor element except that part of the main-surface-side via conductors are connected to the main-surface-side electrode layer disposed in a central region of the sheetlike capacitor element.

(4) In means 1 mentioned above, the multilayer wiring substrate is characterized by comprising, as the via conductor, a plurality of main-surface-side via conductors provided in the interlayer insulating layers of the wiring laminate on the core main-surface and connected to the main-surface-side electrode layer, and a plurality of back-surface-side via conductors provided in the interlayer insulating layers of the wiring laminate on the core back-surface and connected to the back-surface-side electrode layer, and characterized in that the plurality of back-surface-side via conductors are connected to the back-surface-side electrode layer disposed in an outer peripheral region of the sheetlike capacitor element except that part of the back-surface-side via conductors are connected to the back-surface-side electrode layer disposed in a central region of the sheetlike capacitor element.

### DESCRIPTION OF REFERENCE NUMERALS

10: multilayer wiring substrate
11: core substrate
12: core main-surface
13: core back-surface
31: main-surface-side build-up layer as wiring laminate
32: back-surface-side build-up layer as wiring laminate
33, 34, 35, 36, 37, 38: interlayer insulating layer
41, 42: conductor layer
43: main-surface-side via conductor as via conductor
47: back-surface-side via conductor as via conductor
90: accommodation hole
91: inner wall surface of accommodation hole
92: resin filler
101, 131: sheetlike capacitor element
102: element main-surface
103: element back-surface
105, 132: main-surface-side electrode layer
106, 137: back-surface-side electrode layer
107, 135: dielectric layer

What is claimed is:

1. A multilayer wiring substrate comprising:
a core substrate having a core main-surface and a core back-surface and having an accommodation hole which opens at least at the core main-surface side; and
a wiring laminate in which interlayer insulating layers and conductor layers are alternatingly laminated on at least the core main-surface,
the multilayer wiring substrate being characterized by further comprising:
a sheetlike capacitor element having an element main-surface and an element back-surface, configured such that a single dielectric layer is sandwiched directly between a main-surface-side electrode layer exposed at the element main-surface side and a back-surface-side electrode layer exposed at the element back-surface side, and accommodated at least partially in the accommodation hole such that the core main-surface and the element main-surface face the same direction;
a resin filler charged into a gap between the sheetlike capacitor element and an inner wall surface of the accommodation hole formed in the core substrate; and
a via conductor provided in at least the interlayer insulating layers of the wiring laminate on the core main-surface and connected to at least the main-surface-side electrode layer.

2. A multilayer wiring substrate according to claim 1, wherein the core substrate has a thickness of 15 μm to 100 μm.

3. A multilayer wiring substrate according to claim 1, wherein the thicknesses of the main-surface-side electrode layer and the back-surface-side electrode layer are greater than the thickness of the dielectric layer and smaller than the thickness of the core substrate.

4. A multilayer wiring substrate according to claim 1, wherein
the multilayer wiring substrate comprises, as the via conductor, one or a plurality of main-surface-side via conductors provided in the interlayer insulating layers of the wiring laminate on the core main-surface and connected to the main-surface-side electrode layer, and one or a plurality of back-surface-side via conductors provided in the interlayer insulating layers of the wiring laminate on the core back-surface and connected to the back-surface-side electrode layer; and
the number of the main-surface-side via conductor(s) and the number of the back-surface-side via conductor(s) are equal to each other.

5. A multilayer wiring substrate according to claim 1, wherein
the multilayer wiring substrate comprises, as the via conductor, a plurality of main-surface-side via conductors provided in the interlayer insulating layers of the wiring laminate on the core main-surface and connected to the main-surface-side electrode layer, and a plurality of back-surface-side via conductors provided in the interlayer insulating layers of the wiring laminate on the core back-surface and connected to the back-surface-side electrode layer;
the plurality of main-surface-side via conductors are connected to the main-surface-side electrode layer disposed in an outer peripheral region of the sheetlike capacitor element except that part of the main-surface-side via conductors are connected to the main-surface-side electrode layer disposed in a central region of the sheetlike capacitor element; and
the plurality of back-surface-side via conductors are connected to the back-surface-side electrode layer disposed in an outer peripheral region of the sheetlike capacitor element except that part of the back-surface-side via conductors are connected to the back-surface-side electrode layer disposed in a central region of the sheetlike capacitor element.
